(19) United States
(12) Patent Application Publication
(10) Pub. No.: US 2026/0130256 A1
(43) Pub. Date: May 7, 2026

(54) FLUX CLEANING JIG

(71) Applicant: Samsung Electronics Co., Ltd., Suwon-si (KR)

(72) Inventor: SOONCHUL LEE, Suwon-si (KR)

(21) Appl. No.: 19/288,472

(22) Filed: Aug. 1, 2025

(30) Foreign Application Priority Data
Nov. 4, 2024 (KR) 10-2024-0154524

(51) Int. Cl. H01L 23/00

(52) U.S. Cl. CPC H10W 72/072; H10W 72/0198; H10W 72/07118

(57) ABSTRACT

One embodiment of the present disclosure provides a flux cleaning jig including a lower jig on which a substrate to which a plurality of semiconductor chips is attached by conductive bumps is configured to be seated, and an upper jig disposed on the lower jig, and having a plurality of openings in which at least a portion on the semiconductor chips are configured to be disposed, the upper jig including a partition disposed between adjacent openings from among the plurality of openings, and a frame surrounding the partition, in which the partition includes a section in which a width increases in a direction from the upper jig toward the lower jig.

### CROSS-REFERENCE TO RELATED APPLICATION

This application claims priority to and the benefit of Korean Patent Application No. 10-2024-0154524 filed in the Korean Intellectual Property Office on Nov. 4, 2024, the entire contents of which are incorporated herein by reference.

### BACKGROUND OF THE INVENTION

### (a) Field of the Invention

The present disclosure relates to a flux cleaning jig.

### (b) Description of the Related Art

A flip chip bonding technology has been known in a semiconductor package industrial field as a technology for attaching solder bumps on semiconductor chips, aligning the semiconductor chips, to which the solder bumps are attached, on a substrate, and then connecting the semiconductor chips to the substrate by performing a reflow process at a high temperature. The flip chip bonding technology is advantageous in enabling high-speed data transmission and miniaturization and high-performance of products.

During flip chip bonding, flux is used to smoothly bond the solder bump to the substrate. In case that a flux residue remains after the reflow process is completed, there may occur a problem in that a bonding force between a surface of the semiconductor chip and an EMC deteriorates, and electrical reliability deteriorates.

### SUMMARY OF THE INVENTION

The present disclosure provides a jig capable of improving flux cleaning efficiency.

According to an embodiment, a flux cleaning jig includes: a lower jig on which a substrate to which a plurality of semiconductor chips is attached by conductive bumps is seated; and an upper jig disposed on the substrate, which is seated on the lower jig, and having a plurality of openings in which at least a portion on the semiconductor chips are disposed, the upper jig including partition portion disposed between the plurality of openings, and a frame configured to surround the partition portion, in which the partition portion includes a section in which a width increases in a first direction from the upper jig toward the lower jig.

According to another embodiment, a flux cleaning jig includes: a lower jig on which a substrate to which a plurality of semiconductor chips is attached by conductive bumps is seated; an upper jig disposed on the substrate, which is seated on the lower jig, and having a plurality of openings in which at least a portion on the semiconductor chips are disposed, the upper jig including partition portion disposed between the plurality of openings, and a frame configured to surround the partition portion; and a plurality of first support structures coupled to a lower surface of the upper jig and configured to press the substrate seated on the lower jig.

According to another embodiment, a flux cleaning jig includes: a lower jig on which a substrate to which a plurality of semiconductor chips is attached by conductive bumps is seated; an upper jig disposed on the substrate, which is seated on the lower jig, and having a plurality of openings in which at least a portion on the semiconductor chips are disposed, the upper jig including partition portion disposed between the plurality of openings, and a frame configured to surround the partition portion; and a plurality of support structures coupled to a lower surface of the upper jig and configured to press the substrate seated on the lower jig, in which the partition portion includes a section in which a width increases in a direction from the upper jig toward the lower jig.

According to another embodiment, a method of cleaning a substrate using a flux cleaning jig includes placing a substrate on a lower jig of the flux cleaning jig, the substrate having a semiconductor chip attached thereto; placing an upper jig of the flux cleaning jig on the substrate such that the semiconductor chip is positioned within an opening formed in the upper jig; applying a cleaning fluid to the substrate and the semiconductor chip, wherein walls of the opening formed in the upper jig are inclined such that the cleaning fluid flows toward the semiconductor chip.

The semiconductor chip may be attached to the substrate using conductive bumps, and in the step of applying the cleaning fluid, the walls of the opening formed in the upper jig may direct the cleaning fluid toward the conductive bumps.

A width of the opening formed in the upper jig may be larger than a width of the semiconductor chip.

A height of the walls of the opening formed in the upper jig may be larger than a sum of a height of the semiconductor chip and a height of the conductive bumps.

According to one or more aspects of the present disclosure, it is possible to provide the jig capable of improving the flux cleaning efficiency.

### BRIEF DESCRIPTION OF THE DRAWINGS

FIG. 1 is a view illustrating a state before an upper jig and a lower jig of a flux cleaning jig according to an embodiment are coupled.

FIG. 2 is a top plan view of the lower jig illustrated in FIG. 1.

FIG. 3 is a top plan view of the upper jig illustrated in FIG. 1.

FIG. 4 is a partially enlarged cross-sectional view illustrating a state in which a substrate is coupled to the flux cleaning jig according to the embodiment.

FIGS. 5 and 6 are views for explaining a flux cleaning process using the flux cleaning jig according to the embodiment.

FIGS. 7 to 10 are partially enlarged cross-sectional views illustrating a state in which the substrate is coupled to the flux cleaning jig according to a modified example.

FIG. 11 is a view illustrating a state before an upper jig and a lower jig of a flux cleaning jig according to another embodiment are coupled.

FIG. 12 is a top plan view of the lower jig illustrated in FIG. 11.

FIG. 13 is a top plan view of the upper jig illustrated in FIG. 11.

FIG. 14 is a partially enlarged cross-sectional view illustrating a state in which a substrate is coupled to the flux cleaning jig according to another embodiment.

FIGS. 15 and 16 are views illustrating a discharge route for a cleaning liquid in the flux cleaning jig according to another embodiment.

FIG. 17 is a view illustrating a state before an upper jig and a lower jig of a flux cleaning jig according to still another embodiment are coupled.

FIGS. 18 to 22 are partially enlarged cross-sectional views illustrating a state in which the substrate is coupled to the flux cleaning jig according to a modified example.

FIG. 23 shows an example method of cleaning a substrate using a flux cleaning jig according to an embodiment.

### DETAILED DESCRIPTION OF THE EMBODIMENTS

Hereinafter, several embodiments of the present disclosure will be described in detail with reference to the accompanying drawings so that those with ordinary skill in the art to which the present disclosure pertains may easily carry out the embodiments. The present disclosure may be implemented in various different ways and is not limited to the embodiments described herein.

A part irrelevant to the description will be omitted to clearly describe the present disclosure, and the same or similar constituent elements will be designated by the same reference numerals throughout the specification.

In addition, a size and thickness of each constituent element illustrated in the drawings are arbitrarily shown for convenience of description, but the present disclosure is not limited thereto. In order to clearly describe several layers and regions, thicknesses thereof may be enlarged or made smaller in the drawings. In the drawings, the thicknesses of some layers and regions may be exaggerated for convenience of description.

Throughout this specification, when one constituent element is referred to as being “connected to” another constituent element, one constituent element can be “directly connected to” the other constituent element, and one constituent element can also be “indirectly connected to” the other constituent element with other constituent elements therebetween. Similarly, when one constituent element is referred to as being “connected to” another constituent element, one constituent element can be “physically connected to” the other constituent element, and one constituent element can also be “electrically connected to” the other constituent element with other constituent elements therebetween.

In addition, when one component such as a layer, a film, an area, or a plate is described as being positioned “above” or “on” another component, one component can be positioned “directly on” another component, and one component can also be positioned on another component with other components interposed therebetween. On the contrary, when one component is described as being positioned “directly above” another component, there is no component therebetween. In addition, when a component is described as being positioned “above” or “on” a reference part, the component may be positioned “above” or “below” the reference part, and this configuration does not necessarily mean that the component is positioned “above” or “on” the reference part in a direction opposite to gravity.

Throughout the specification, unless explicitly described to the contrary, the term “comprise/include” and variations such as “comprises/includes” or “comprising/including” will be understood to imply the inclusion of stated elements, not the exclusion of any other elements.

In addition, throughout the specification, the phrase “in a plan view” means when an object is viewed from above, and the phrase “in a cross-sectional view” means when a cross section made by vertically cutting an object is viewed from a lateral side.

Further, throughout the specification, numerical designations such as first, second, and the like are used to distinguish one component from other components that are identical or similar thereto and are not necessarily intended to refer to a particular component. Therefore, a configuration referred to as a first component in certain parts of the present specification may be referred to as a second component in other parts of the present specification.

In addition, throughout the specification, references to any singular component include references to a plurality of components unless specifically stated to the contrary.

Also, throughout the specification, references to orientations such as an upper surface, an upper side, an upper portion, a lower surface, a lower side, and a lower portion are intended to assist in describing and understanding the present specification with reference to the drawings.

Hereinafter, a flux cleaning jig according to embodiments of the present disclosure will be described with reference to the drawings.

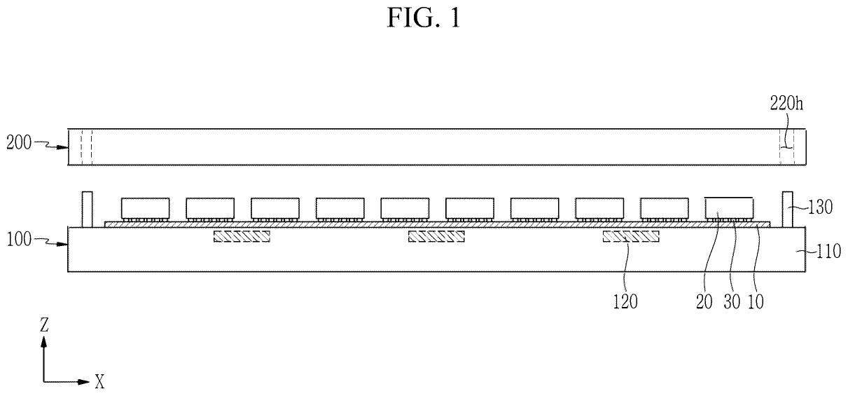

FIG. 1 is a view illustrating a state before an upper jig and a lower jig of a flux cleaning jig according to the embodiment are coupled.

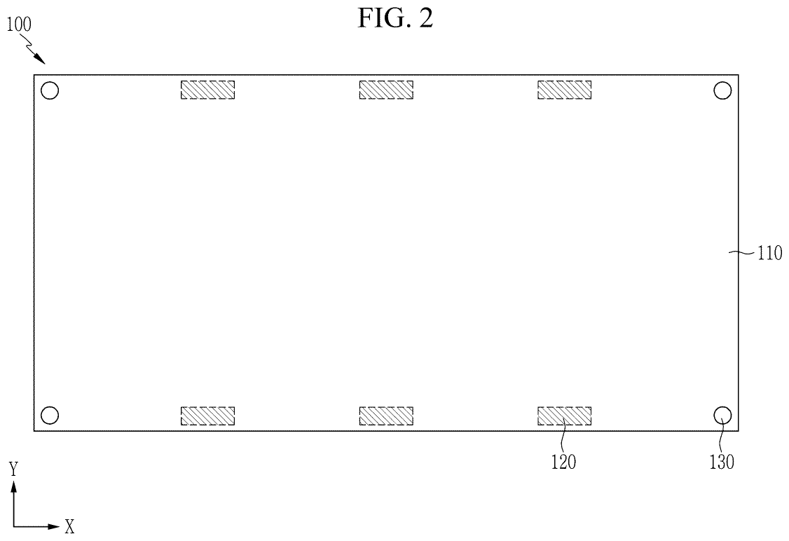

FIG. 2 is a top plan view of the lower jig illustrated in FIG. 1.

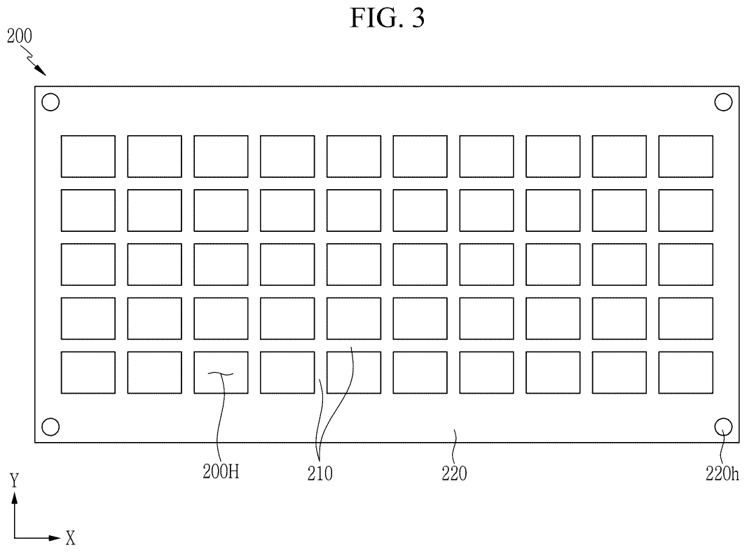

FIG. 3 is a top plan view of the upper jig illustrated in FIG. 1.

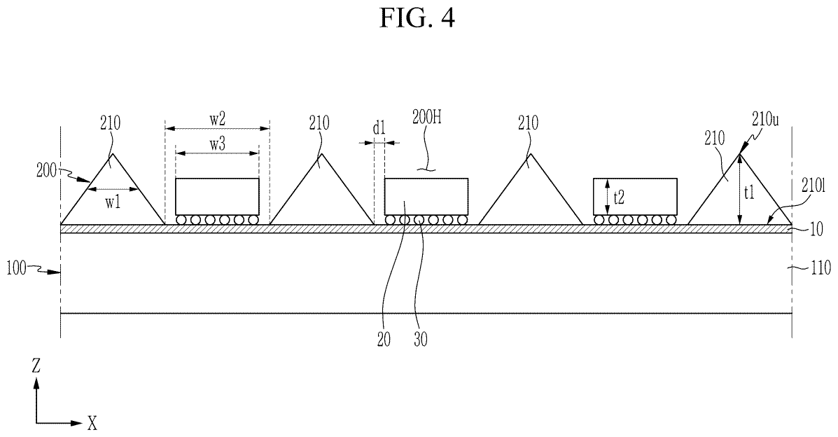

FIG. 4 is a partially enlarged cross-sectional view illustrating a state in which a substrate is coupled to the flux cleaning jig according to the embodiment.

A flux cleaning jig according to an embodiment includes a lower jig 100 and an upper jig 200.

A substrate 10 may be seated on the lower jig 100, and a plurality of semiconductor chips 20 may be attached (flip-chip bonded) to the substrate 10 by conductive bumps 30.

The substrate 10 may be, for example, a printed circuit board (PCB).

The type of semiconductor chip 20 is not specially limited. The semiconductor chip 20 may be a logic chip, a memory chip, a system-on-chip, or the like.

The conductive bump 30 may be disposed between the semiconductor chip 20 and the substrate 10 and physically and electrically connect the semiconductor chip 20 to the substrate 10. A conductive material, e.g., solder may be used as a material of the conductive bump 30.

The lower jig 100 may include a main body 110, magnets 120 embedded in the main body 110, and protruding portions (e.g., protrusions) 130.

The main body 110 may support the substrate 10 and the upper jig 200 and have a plate shape. Metal, such as iron (Fe), stainless steel, or aluminum (Al), may be used as a material of the main body 110.

As described below, in the embodiment in which the flux cleaning jig includes a second support structure 320, the main body 110 may include a magnetic material, particularly, a ferromagnetic material so as to be coupled to the second support structure 320 including the magnet. For example, the main body 110 may include at least one of iron (Fe), cobalt (Co), nickel (Ni), martensite-type stainless steel, and ferrite-type stainless steel.

The magnet 120 may be embedded in the main body 110. The magnet 120 may attract the upper jig 200 by means of a magnetic force and strongly couple the lower jig 100 to the upper jig 200. The material, the thickness, and the like of the substrate 10 interposed between the magnet 120 and the upper jig 200 may be appropriately designed not to hinder the coupling between the lower jig 100 and the upper jig 200. In order to ensure an embedment space, the magnet 120 may be embedded in a region of the main body 110 that overlaps a frame 220 of the upper jig 200 when viewed in a plan view. The number of magnets 120 is not specially limited. The magnets 120 may be larger or smaller in number than those illustrated in the drawings.

The protruding portion 130 may protrude in a Z direction Z from the main body 110 toward the upper jig 200. The protruding portions 130 may be inserted into holes 220h formed in the frame 220 of the upper jig 200 and may fix the coupling positions of the lower jig 100 and the upper jig 200 with respect to each other. A material of the protruding portion 130 may be identical to or different from a material of the main body 110. The protruding portion 130 and the main body 110 may be integrated without having a boundary, or the protruding portion 130 and the main body 110 may be separately formed while having a boundary. The protruding portion 130 may have a cylindrical shape, but the present disclosure is not limited thereto. The protruding portion 130 may have various shapes such as a quadrangular column shape or a hexagonal column shape. The protruding portion 130 may be formed in a region of the upper jig 200 that overlaps the frame 220 when viewed in a plan view. The number of protruding portions 130 is not particularly limited. The protruding portions 130 may be larger or smaller in number than those illustrated in the drawings.

The upper jig 200 may be disposed on the substrate 10 seated on the lower jig 100 and may press the substrate 10. For example, the upper jig 200 may be disposed on (e.g., above) the lower jig 100.

The upper jig 200 may have a plurality of openings 200H in which at least a portion of the semiconductors chips 20 are respectively disposed. The upper jig 200 may include partition portion (e.g., partition) 210 extending between the plurality of openings 200H, and the frame 220 configured to surround the partition portion 210 (see, e.g., FIG. 3). In the present disclosure, the terms “the partition portion 210″ and ”the frame 220″ are used to distinguish the regions of the upper jig 200. However, the partition portion 210 and the frame 220 may not have a boundary. For example, the partition portion 210 and the frame 220 may be formed of the same material and/or may be integrated with each other.

The semiconductor chip 20 may be disposed in each of the opening 200H, and the opening 200H may be surrounded by the partition portion 210. For example, each one of the semiconductor chips 20 may be disposed in a corresponding opening 200H. As described below, the partition portion 210 may be spaced apart from the semiconductor chip 20. Therefore, a width w2 of the opening 200H may be larger than a width w3 of the semiconductor chip 20 (see, e.g., FIG. 4). In the present disclosure, the ‘width’ means a width in an X direction X and/or a Y direction Y. The opening 200H may have a shape similar to the semiconductor chip 20, e.g., a quadrangular shape.

The substrate 10 may be disposed to extend below the openings 200H. For example, the substrate 10 may be positioned below the openings 200H. Therefore, the substrate 10 may be pressed by the partition portion 210 of the upper jig 200 and fixed onto the lower jig 100. A part of the substrate 10, e.g., an edge region of the substrate 10 may be disposed below the frame 220 and pressed by the frame 220.

The partition portion 210 may have a lattice shape. That is, the partition portion 210 may have a shape in which the regions extending in the X direction and the regions extending in the Y direction intersect one another.

The partition portion 210 may be spaced apart from the semiconductor chips 20 so that a cleaning liquid may penetrate under the semiconductor chips 20 to contact the conductive bumps 30. In addition, the partition portion 210 and the semiconductor chips 20 may be spaced apart from one another at predetermined distances to facilitate the alignment of the semiconductor chips 20 and ensure the alignment margin. For example, a gap d1 between the partition portion 210 and the semiconductor chip 20 may be 100 μm or more.

However, the distance between the partition portion 210 and the semiconductor chip 20 may be kept within an appropriate distance in order to efficiently deliver the cleaning liquid to the semiconductor chip 20 and efficiently dispose the semiconductor chips 20 on the substrate 10. For example, the gap d1 between the partition portion 210 and the semiconductor chip 20 may be 100 to 500 μm, 200 to 400 μm, or about 300 μm.

In the present disclosure, the partition portion 210 may include a section in which a width w1 increases in a downward direction (a −Z direction Z) from the upper jig 200 toward the lower jig 100. Therefore, the partition portion 210 may have an inclined shape so that the partition portion 210 becomes wider in the downward direction. A position of the section in which the width w1 of the partition portion 210 increases may be appropriately adjusted so that the cleaning liquid may be sprayed directly to the flux remaining adjacent to the conductive bump 30.

A thickness of the section, in which the width w1 of the partition portion 210 is increased in the downward direction (the −Z direction), may be larger than a thickness of the remaining section of the partition portion 210, i.e., a thickness of the section in which the width w1 is constant or decreased in the downward direction (the −Z direction) so that a falling position on the partition portion 210 on which a cleaning liquid 40 falls is designed to be sufficiently close to the semiconductor chip 20.

The partition portion 210 may have a maximum width on a lower surface 210l that faces the substrate 10. The width of the lower surface 210l of the partition portion 210 may be formed to be large, such that the substrate 10 may be stably pressed and fixed.

The partition portion 210 may have a vertically symmetric cross-sectional shape. However, the present disclosure is not limited thereto.

In the embodiment, the width w1 of the partition portion 210 may gradually increase (or at a constant ratio) in the downward direction from the upper jig 200 toward the lower jig 100. For example, the partition portion 210 may have a triangular cross-sectional shape.

In order to adjust the spray position of the cleaning liquid and remove the flux residue remaining around the semiconductor chip and protect the semiconductor chip during the cleaning process, a thickness t1 (e.g., a maximum thickness) of the partition portion 210 may be larger than a thickness t2 of the semiconductor chip 20. For example, the thickness t2 of the semiconductor chip 20 may be several tens to several hundreds of microns (μm), and the thickness t1 of the partition portion 210 may be several millimeters, e.g., about 2 to 3 mm. The thickness t1 of the partition portion 210 may be larger than a sum of the thickness t2 of the semiconductor chip 20 and the thickness of the conductive bump 30. Therefore, an upper surface 210u of the partition portion 210 may be positioned at a level higher than the semiconductor chip 20. In the present disclosure, the ‘thickness’ means a thickness in the Z direction Z.

The frame 220 may constitute an edge of the upper jig 200 and surround the partition portion 210 when viewed in a plan view. The partition portion 210 may be understood as being disposed between adjacent openings of the openings 200H. Therefore, the frame 220 may be understood as surrounding the openings 200H.

The frame 220 may have the holes 220h into which the protruding portions 130 of the lower jig 100 are inserted. The holes 220h may accommodate the protruding portions 130 and fix the coupling positions of the lower jig 100 and the upper jig 200 with respect to each other. The hole 220h may have a shape corresponding to the protruding portion 130.

Metal, such as iron (Fe), stainless steel, or aluminum (Al), may be used as a material of the upper jig 200.

As described below, in the embodiment in which the flux cleaning jig includes the second support structure 320, the upper jig 200 may include a magnetic material, particularly, a ferromagnetic material so as to be coupled to the second support structure 320 including the magnet. For example, the upper jig 200 may include at least one of iron (Fe), cobalt (Co), nickel (Ni), martensite-type stainless steel, and ferrite-type stainless steel.

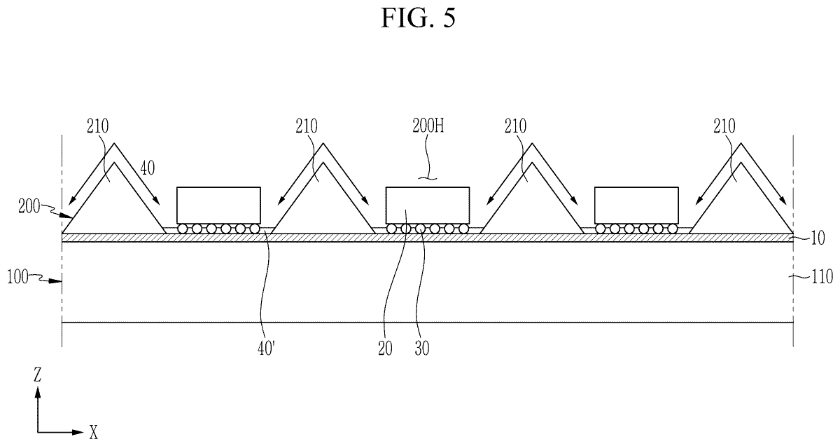

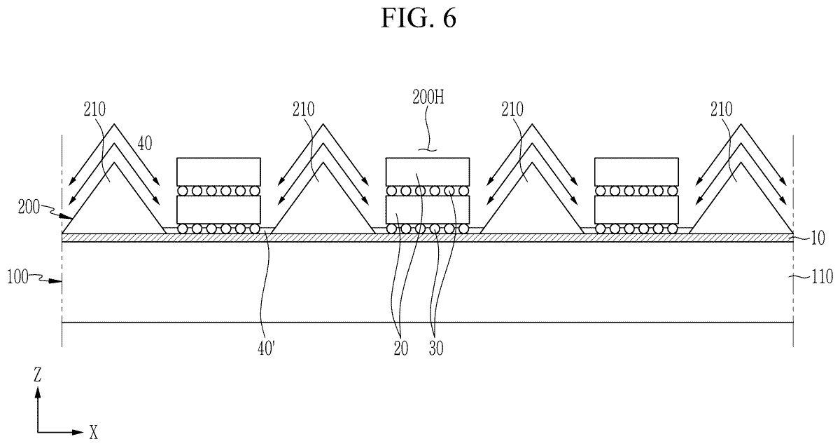

FIGS. 5 and 6 are views for explaining a flux cleaning process using the flux cleaning jig according to the embodiment.

In case that the partition portion 210 has a constant width (e.g., has a quadrangular cross-sectional shape), unlike the present disclosure, the cleaning liquid sprayed onto the partition portion 210 may not penetrate into the lower sides of the semiconductor chips 20, which makes it difficult to spray the cleaning liquid to the flux remaining on the conductive bumps 30 and the like. In particular, because the distance between the semiconductor chip 20 and the upper jig 200 decreases in accordance with the increase in number of arranged PCBs, it may be further difficult for the cleaning liquid to penetrate into the lower sides of the semiconductor chips 20. In addition, in a stack chip structure (e.g., HBM) in which two or more semiconductor chips 20 are stacked, it may be difficult for the cleaning liquid to be uniformly sprayed to the lower sides of the upper semiconductor chips and the lower sides of the lower semiconductor chips.

According to the present disclosure, the partition portion 210 has a shape inclined toward the semiconductor chip 20, such that the cleaning liquid 40 is sprayed directly to the conductive bump 30, thereby improving the flux cleaning efficiency. In addition, in the stack chip structure in which two or more semiconductor chips 20 are stacked, it is possible to uniformly improve the flux cleaning efficiency on the lower semiconductor chip and the upper semiconductor chip (see FIG. 6). Therefore, it is possible to prevent the problems such as a deterioration in a bonding force between a surface of the semiconductor chip and an EMC and a deterioration in electrical reliability caused by the flux residue.

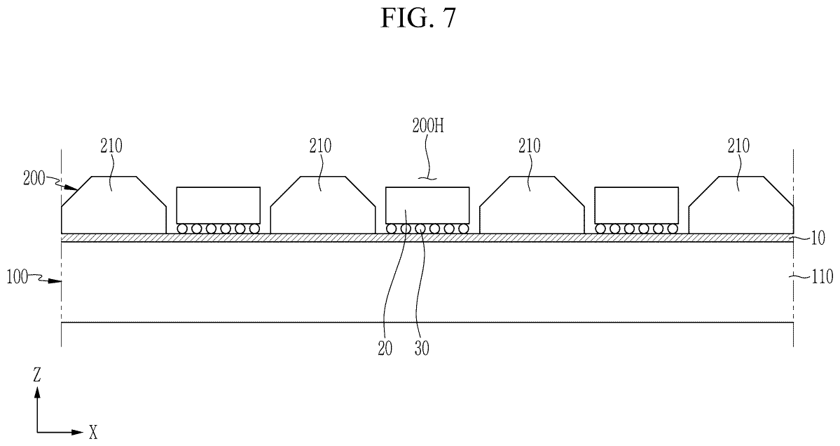

FIGS. 7 to 10 are partially enlarged cross-sectional views illustrating a state in which the substrate is coupled to the flux cleaning jig according to a modified example.

In the embodiment, the width of the partition portion 210 of the upper jig 200 may increase from a top thereof in a downward direction and then may become constant in the downward direction (see FIG. 7).

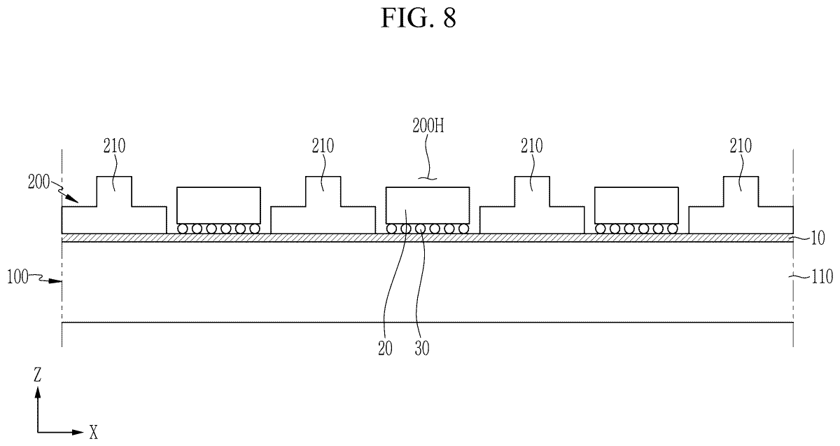

In the embodiment, the partition portion 210 may include an upper region having a constant first width, and a lower region having a constant second width larger than the first width (see FIG. 8).

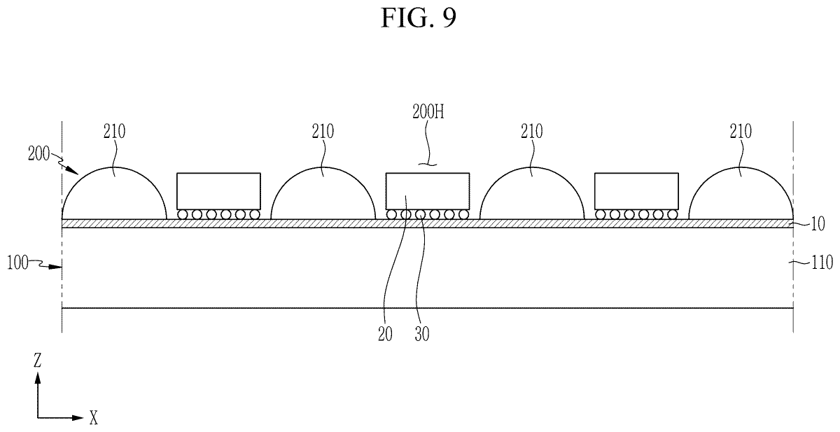

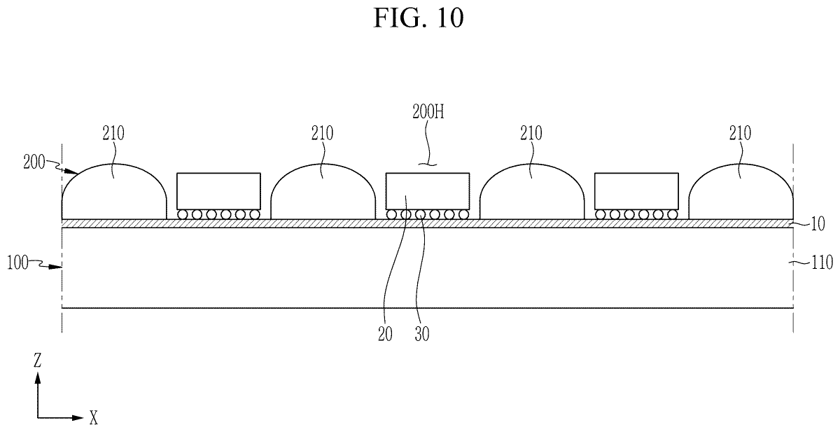

In the embodiment, the partition portion 210 may include a curved surface, e.g., a semicircular cross-sectional shape or a semi-circular arcuate cross-sectional shape (see FIGS. 9 and 10).

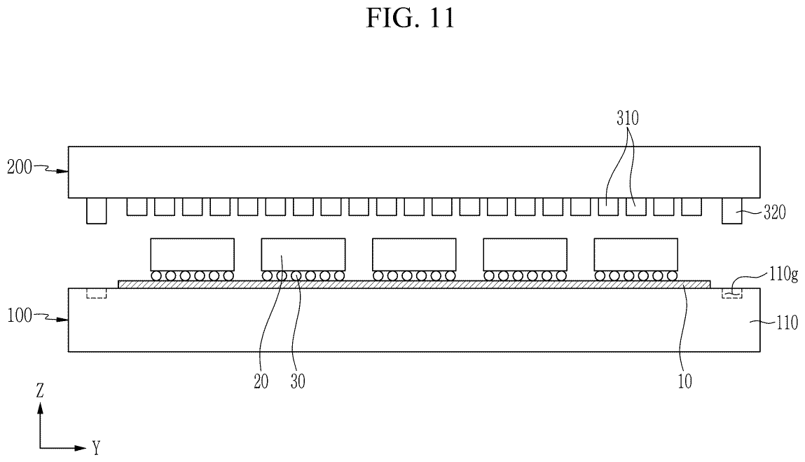

FIG. 11 is a view illustrating a state before an upper jig and a lower jig of a flux cleaning jig according to another embodiment are coupled.

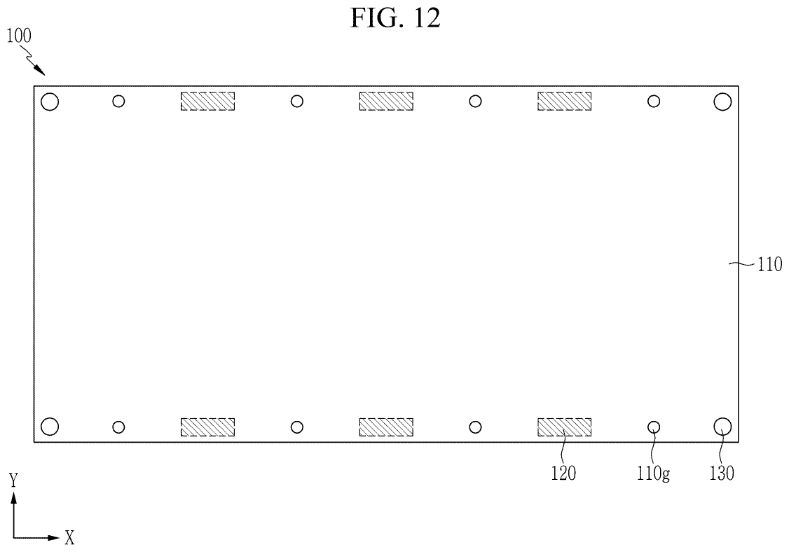

FIG. 12 is a top plan view of the lower jig illustrated in FIG. 11.

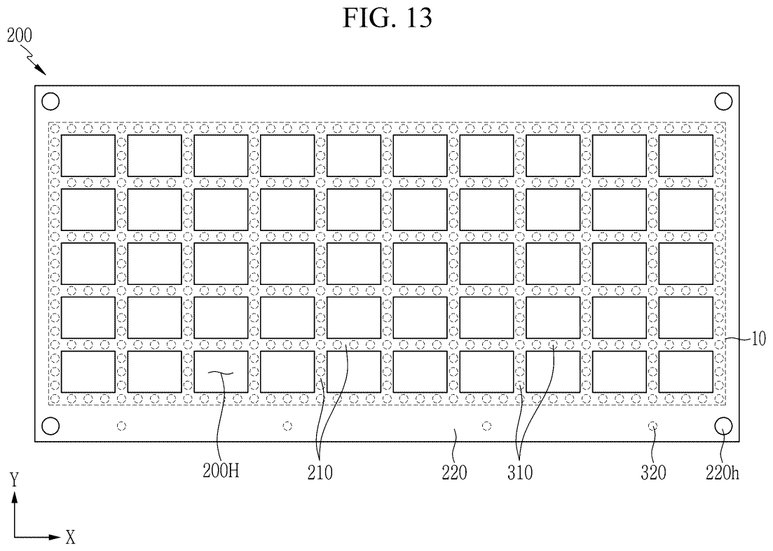

FIG. 13 is a top plan view of the upper jig illustrated in FIG. 11.

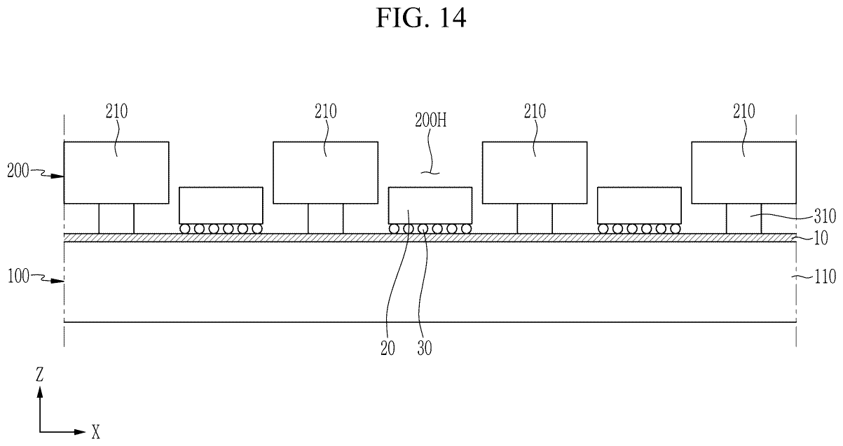

FIG. 14 is a partially enlarged cross-sectional view illustrating a state in which a substrate is coupled to the flux cleaning jig according to another embodiment.

The flux cleaning jig according to another embodiment may further include support structures (e.g., supports, support pillars, support posts, pillars, or posts) 310 and 320 in addition to the lower jig 100 and the upper jig 200.

The support structures 310 and 320 may be disposed between the upper jig 200 and the lower jig 100 and space the upper jig 200 apart from the lower jig 100, thereby providing discharge routes for the cleaning liquid. That is, the cleaning liquid, in which the flux is dissolved after the cleaning process, may be discharged between the support structures 310 and 320. Therefore, it is possible to prevent the cleaning liquid from accumulating on the substrate 10 during the flux cleaning process. In addition, the cleaning liquid, in which the flux is dissolved, is discharged, and the clean cleaning liquid is consistently introduced (the cleaning liquid is circulated), such that the solubility of the flux into the cleaning liquid may increase.

The support structures 310 and 320 may include first support structures 310 and further include the second support structures 320.

The first support structures 310 may be connected to the lower surface of the upper jig 200 and press the substrate 10 seated on the lower jig 100. For example, the first support structure 310 may be in contact with the substrate 10 seated on the lower jig 100 and directly press the substrate 10.

The first support structure 310 may be formed independent from the upper jig 200 and may be coupled to the lower surface of the upper jig 200. The method of coupling the first support structure 310 to the upper jig 200 is not particularly limited. For example, a direct coupling method using welding or compressing or an indirect coupling method using soldering or bonding agents may be used. The first support structure 310 and the upper jig 200 may be coupled to each other by a magnetic force. Alternatively, the first support structure 310 may be integrated with the upper jig 200 while protruding from the lower surface of the upper jig 200. In this case, the first support structure 310 may not have a boundary with the upper jig 200.

In the embodiment, the first support structure 310 may include a magnet. The first support structure 310 including the magnet may be strongly coupled to the upper jig 200 and/or the lower jig 100 by a magnetic force. At least one of the lower jig 100 and the upper jig 200 may include a magnetic material so as to be coupled to the first support structure 310. The magnetic material may include at least one of iron (Fe), cobalt (Co), nickel (Ni), martensite-type stainless steel, and ferrite-type stainless steel.

The first support structures 310 may be arranged to surround the semiconductor chips 20 in a state in which the substrate 10 is pressed between the lower jig 100 and the upper jig 200. All or most of the first support structures 310 may be disposed on the lower surface of the partition portion 210. Some of the first support structures 310 (the first support structures 310 disposed at the outermost side based on the drawings) may be disposed on the lower surface of the frame 220 while having shapes that surround the outermost openings 200H.

The first support structures 310 may be spaced apart from one another at predetermined distances. The distances at which the first support structures 310 are spaced apart from one another may be appropriately adjusted so that the cleaning liquid may be discharged at an appropriate speed.

The second support structure 320 may be disposed between the lower jig 100 and the frame 220 of the upper jig 200 and may connect the lower jig 100 to the upper jig 200.

The second support structure 320 may be disposed outside the substrate 10. For example, when viewed in a plan view, the second support structure 320 may not overlap the substrate 10 in a state in which the substrate 10 is pressed between the lower jig 100 and the upper jig 200. Therefore, unlike the first support structure 310 being in contact with the substrate 10, the second support structure 320 may be in contact with the lower jig 100. In order to implement the contact with the lower jig 100, a thickness of the second support structure 320 may be larger than a thickness of the first support structure 310. For example, a vertical dimension (e.g., a height) of the second support structure 320 may be larger than a vertical dimension of the first support structure 310.

In the embodiment, the second support structure 320 may be coupled to the lower jig 100 in a state in which the second support structure 320, together with the first support structure 310, is coupled to the lower surface of the upper jig 200 (the frame 220). The method of coupling the second support structure 320 to the upper jig 200 is not specially limited. For example, a direct coupling method using welding or compressing or an indirect coupling method using soldering or bonding agents may be used. The second support structure 320 and the upper jig 200 may be coupled to each other by a magnetic force. Alternatively, the second support structure 320 may be integrated with the upper jig 200 while protruding from the lower surface of the upper jig 200. In this case, the second support structure 320 may not have a boundary with the upper jig 200.

In the embodiment, the second support structure 320 may include a magnet. The second support structure 320 including the magnet may strongly couple the lower jig 100 to the upper jig 200 by a magnetic force. As described above, at least one of the lower jig 100 and the upper jig 200 may include the magnetic material.

The lower jig 100 may have grooves 110g into which one end (e.g., the lower end) of the second support structure 320 is inserted. The groove 110g may be formed in the main body 110 of the lower jig 100. The groove 110g may provide alignment positions of the second support structure 320 and the lower jig 100 and fix the coupling positions of the second support structure 320 and the lower jig 100 with respect to each other.

In the embodiment including the support structures 310 and 320, the remaining flux may be primarily cleaned by the cleaning liquid sprayed onto the partition portion 210 and additionally cleaned by the cleaning liquid flowing along the discharge route.

In the embodiment including the support structures 310 and 320, the cross-sectional shape of the partition portion 210 is not specially limited. Even in case that the partition portion 210 has a square or rectangular cross-sectional shape, the flux cleaning efficiency may be improved by the cleaning liquid flowing along the discharge route.

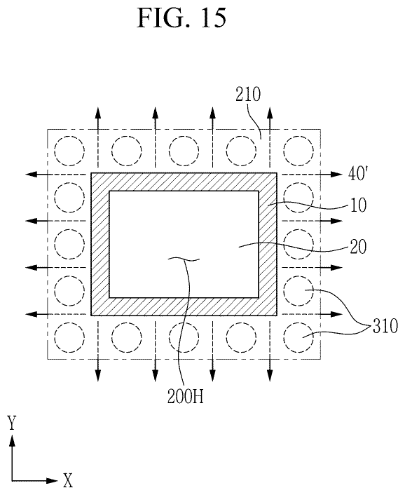

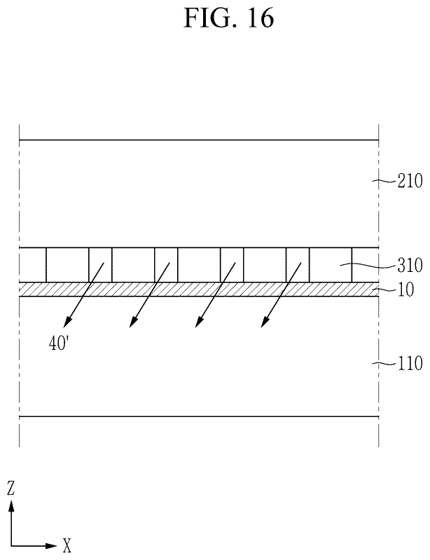

FIGS. 15 and 16 are views illustrating a discharge route for a cleaning liquid in the flux cleaning jig according to another embodiment.

According to the present disclosure, a cleaning liquid 40′, in which the flux is dissolved after the cleaning process, may be discharged between adjacent first support structures 310 from among the first support structures 310. Therefore, it is possible to prevent the cleaning liquid from accumulating on the substrate 10 during the flux cleaning process. In addition, the cleaning liquid 40′, in which the flux is dissolved, is discharged, and the clean cleaning liquid 40 is consistently introduced (e.g., the cleaning liquid is circulated), such that the solubility of the flux into the cleaning liquid may increase.

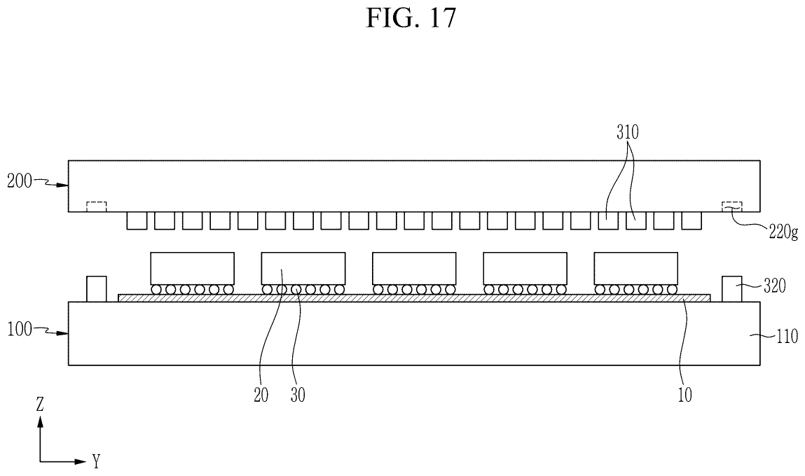

FIG. 17 is a view illustrating a state before an upper jig and a lower jig of a flux cleaning jig according to still another embodiment are coupled.

The second support structure 320 may be coupled to the upper jig 200 (the frame 220) in the state in which the second support structure 320 is coupled to an upper surface of the lower jig 100. The method of coupling the second support structure 320 and the lower jig 100 is not specially limited. For example, a direct coupling method using welding or compressing or an indirect coupling method using soldering or bonding agents may be used. The second support structure 320 and the lower jig 100 may be coupled to each other by a magnetic force. Alternatively, the second support structure 320 may be integrated with the lower jig 100 while protruding from the upper surface of the lower jig 100. In this case, the second support structure 320 may not have a boundary with the lower jig 100.

The frame 220 may have grooves 220g into which one end (e.g., the upper end) of the second support structure 320 is inserted. The groove 220g may provide alignment positions of the second support structure 320 and the upper jig 200 and fix the coupling positions of the second support structure 320 and the upper jig 200 with respect to each other.

As necessary, both the frame 220 and the lower jig 100 may have the grooves 110g and 220g. For example, both the groove 110g and the groove 220g may be present in an embodiment.

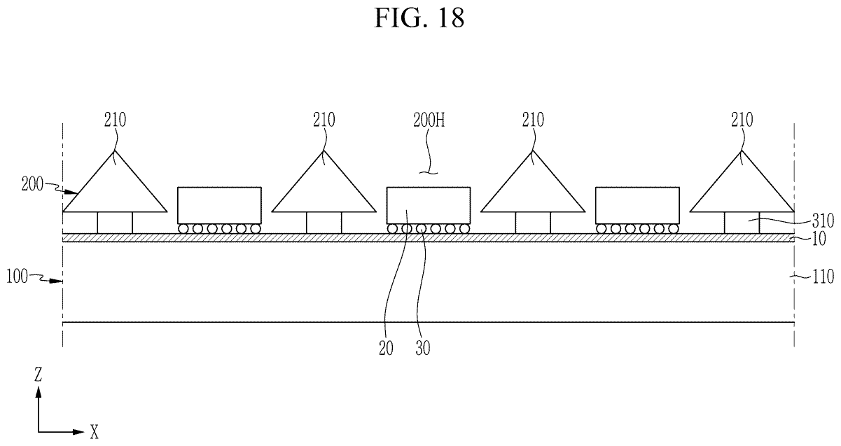

FIGS. 18 to 22 are partially enlarged cross-sectional views illustrating a state in which the substrate is coupled to the flux cleaning jig according to a modified example.

According to the embodiment, the partition portion 210 may include the section in which the width increases in the direction from the upper jig 200 toward the lower jig 100. The partition portion 210 has a shape inclined toward the semiconductor chip 20, such that the flux cleaning efficiency may be further improved by the cleaning liquid primarily sprayed onto the partition portion 210. In addition, it is possible to precisely adjust a spray position of the cleaning liquid by dropping the cleaning liquid from an outer region of the partition portion 210 adjacent to the semiconductor chip 20. The thickness and width of the first support structure 310, the distance from the semiconductor chip 20, and the like may be appropriately adjusted in consideration of the falling position of the cleaning liquid.

In the embodiment, the width of the partition portion 210 may gradually increase (or at a constant ratio) in the downward direction from the upper jig 200 toward the lower jig 100. For example, the partition portion 210 may have a polygonal shape such as a triangular cross-sectional shape (see FIG. 18).

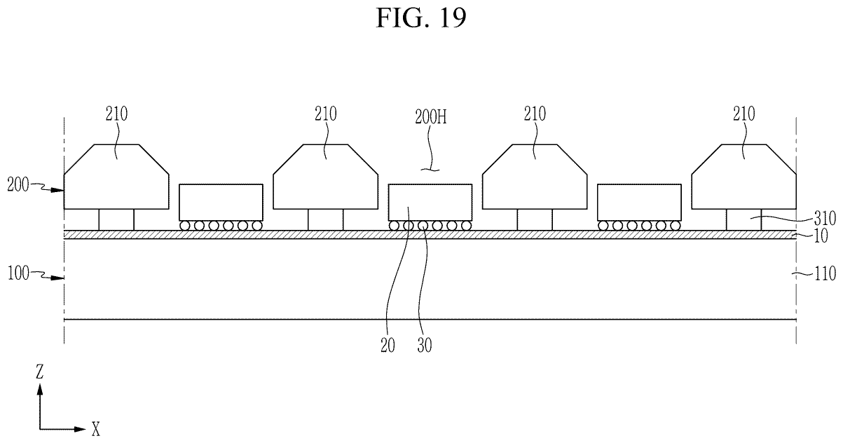

In the embodiment, the width of the partition portion 210 may increase and then become constant downward (see FIG. 19).

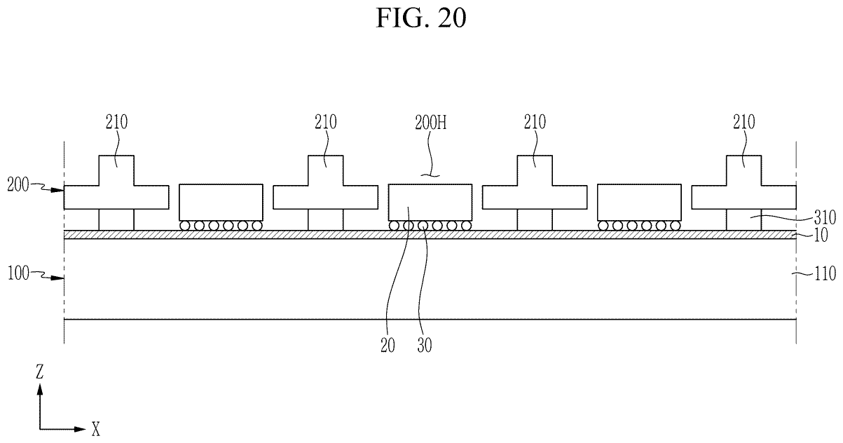

In the embodiment, the partition portion 210 may include an upper region having a first constant width, and a lower region having a second constant width larger than the first constant width (see FIG. 20).

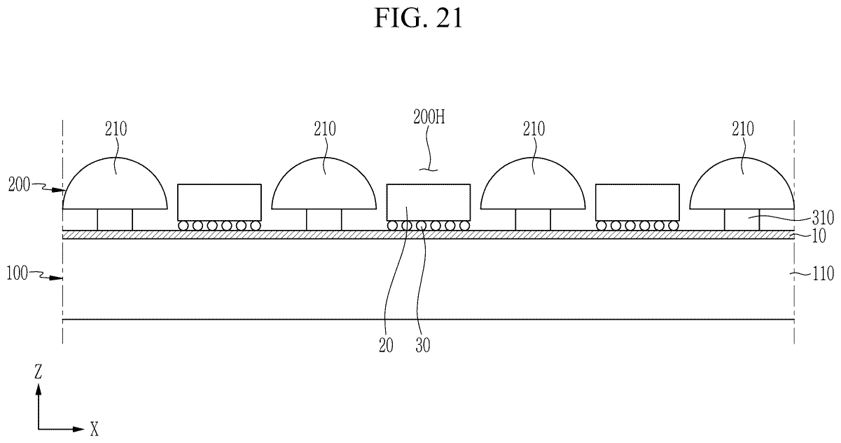

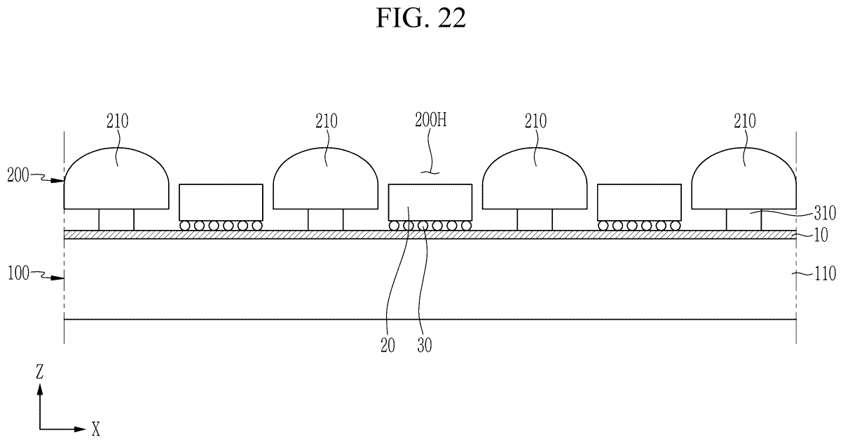

In the embodiment, the partition portion 210 may include a curved surface, e.g., a semicircular cross-sectional shape or a semi-circular arcuate cross-sectional shape (see FIGS. 21 and 22).

In the example embodiments shown in FIGS. 18-22, the first support structure 310 may be positioned between the bottom surface of the partition portion 210 and the top surface of the substrate 10. For example, the first support structure 310 may contact the bottom surface of the partition portion 210 and may contact the top surface of the substrate 10.

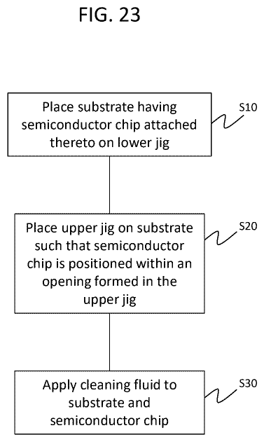

FIG. 23 shows an example method of cleaning a substrate using a flux cleaning jig according to embodiments of the disclosure.

In step S10, a substrate is placed on a lower jig (e.g., lower jig 100) of a flux cleaning jig. A semiconductor chip is attached to the substrate as shown, e.g., in FIG. 1.

In step S20, an upper jig (e.g., upper jig 200) is placed on the substrate such that the semiconductor chip is positioned within an opening formed in the upper jig.

In step S30, a cleaning fluid is applied to the substrate and the semiconductor chip while the semiconductor chip is positioned within the opening formed in the upper jig. Walls of the opening formed in the upper jig are inclined such that the cleaning fluid flows toward the semiconductor chip.

Although the embodiments of the present disclosure have been described in detail above, the right scope of the present disclosure is not limited thereto, and it should be construed that many variations and modifications made by those skilled in the art using the basic concept of the present disclosure, which is defined in the following claims, will also belong to the right scope of the present disclosure.

Further, the embodiments of the present disclosure are not independent of one another and may be carried out in combination with one another unless specifically contradicted. Accordingly, a combination of the embodiments of the present disclosure should be considered as being included in the present disclosure.

What is claimed is:

1. A flux cleaning jig comprising:
a lower jig on which a substrate, to which a plurality of semiconductor chips is attached by conductive bumps, is configured to be seated; and
an upper jig disposed on the lower jig, the upper jig having a plurality of openings in which at least a portion of the semiconductor chips are configured to be disposed, the upper jig comprising a partition disposed between adjacent openings from among the plurality of openings, and the upper jig including a frame surrounding the partition,
wherein the partition comprises a section in which a width increases in a first direction from the upper jig toward the lower jig.

2. The flux cleaning jig of claim 1, wherein:
a width of each opening from among the plurality of openings is larger than a width of each semiconductor chip from among the plurality of semiconductor chips.

3. The flux cleaning jig of claim 2, wherein:
the partition is spaced apart from each semiconductor chip from among the plurality of semiconductor chips.

4. The flux cleaning jig of claim 3, wherein:
a gap between the partition and each semiconductor chip from among the plurality of semiconductor chips is 100 μm or more.

5. The flux cleaning jig of claim 1, wherein:
a thickness of the partition in the first direction is larger than a thickness of each semiconductor chip from among the plurality of semiconductor chips in the first direction.

6. The flux cleaning jig of claim 1, wherein:
the partition has a maximum width in a second direction perpendicular to the first direction at a surface of the partition facing the lower jig.

7. The flux cleaning jig of claim 1, wherein:
the lower jig comprises: a main body; and a magnet embedded in the main body in a region that overlaps the frame when viewed in a plan view, and
the upper jig comprises a magnetic material.

8. The flux cleaning jig of claim 1, wherein:
the lower jig includes a protrusion, and
the frame has a hole into which the protrusion is configured to be inserted.

9. The flux cleaning jig of claim 1, wherein:
the substrate is positioned below the plurality of openings.

10. The flux cleaning jig of claim 1, wherein:
a thickness of the section of the partition, in which the width increases in the first direction, is larger than a thickness of the remaining section, in which the width is constant or decreases in the first direction.

11. A flux cleaning jig comprising:
a lower jig on which a substrate, to which a plurality of semiconductor chips is attached by conductive bumps, is configured to be seated;
an upper jig disposed on the lower jig, the upper jig having a plurality of openings in which at least a portion of the semiconductor chips are disposed, the upper jig comprising a partition disposed between adjacent openings from among the plurality of openings, and the upper jig including a frame surrounding the partition; and
a plurality of first support pillars coupled to a lower surface of the upper jig and configured to press the substrate seated on the lower jig.

12. The flux cleaning jig of claim 11, wherein:
each of the plurality of first support pillars comprises a magnet, and
at least one of the lower jig and the upper jig comprises a magnetic material.

13. The flux cleaning jig of claim 11, wherein:
the plurality of first support pillars are arranged to surround each semiconductor chip from among the plurality of semiconductor chips.

14. The flux cleaning jig of claim 11, further comprising:
a second support pillar disposed between the lower jig and the frame, the second support pillar connecting the lower jig to the upper jig.

15. The flux cleaning jig of claim 14, wherein:
the second support pillar comprises a magnet, and
at least one of the lower jig and the upper jig comprises a magnetic material.

16. The flux cleaning jig of claim 14, wherein:
when viewed in a plan view, the second support pillar does not overlap a region of the lower jig where the substrate is configured to be seated.

17. The flux cleaning jig of claim 16, wherein:
the lower jig has a groove into which one end of the second support pillar is configured to be inserted.

18. The flux cleaning jig of claim 16, wherein:
the frame has a groove into which one end of the second support pillar is configured to be inserted.

19. A flux cleaning jig comprising:
a lower jig on which a substrate, to which a plurality of semiconductor chips is attached by conductive bumps, is configured to be seated;
an upper jig disposed on the lower jig, the upper jig having a plurality of openings in which at least a portion of the semiconductor chips are configured to be disposed, the upper jig comprising a partition disposed between adjacent openings from among the plurality of openings, and the upper jig including a frame surrounding the partition; and
a plurality of support pillars coupled to a lower surface of the upper jig, the plurality of support pillars being configured to press the substrate seated on the lower jig,
wherein the partition comprises a section in which a width increases in a direction from the upper jig toward the lower jig.

20. The flux cleaning jig of claim 19, wherein:
each of the plurality of support pillars comprises a magnet, and
at least one of the lower jig and the upper jig comprises a magnetic material.
